(19) United States
(12) Patent Application Publication
(10) Pub. No.: US 2026/0303082 A1
(43) Pub. Date: Oct. 1, 2026

(54) GATE DRIVER CIRCUIT

(71) Applicant: ROHM CO., LTD., Kyoto-shi (JP)

(72) Inventor: Hisashi SUGIE, Kyoto-shi (JP)

(21) Appl. No.: 19/629,643

(22) Filed: Mar. 26, 2026

(30) Foreign Application Priority Data
Mar. 28, 2025 (JP) 2025-056744

(51) Int. Cl. H03K 17/0812; H02P 27/06; H03K 17/16

(52) U.S. Cl. CPC H03K 17/08122; H03K 17/162; H02P 27/06; H03K 2217/0009; H03K 2217/0027; H03K 2217/0036; H03K 2217/0063; H03K 2217/0072

(57) ABSTRACT

A driving capability of a high-side driver is switchable in multiple stages including a first capability, a second capability, and a third capability. A first output detection signal generated by a first output sensor takes a first level when an output voltage is higher than a threshold voltage and takes a second level when the output voltage is lower. In a source mode, a control circuit is configured to: set the driving capability of the high-side driver to the first capability when an instruction for transition from a high output state to a high impedance state occurs; set the driving capability of the high-side driver to the second capability when the first output detection signal changes to the second level; and set the driving capability of the high-side driver to the third capability when assertion of a high-side OFF detection signal occurs.

### CROSS REFERENCE TO RELATED APPLICATIONS

The present invention claims priority under 35 U.S.C. § 119 to Japanese Application No. 2025-056744, filed on Mar. 28, 2025, the entire contents of which being incorporated herein by reference.

### BACKGROUND

### 1. Technical Field

The present disclosure relates to a gate driver circuit.

### 2. Description of Related Art

Half-bridge circuits, H-bridge circuits, and three-phase bridge circuits (hereinafter collectively referred to as “switching circuits”) using power transistors are used in motor driver circuits, DC/DC converters, power conversion devices, and the like.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures.

FIG. 1 is a circuit diagram for explaining switching of a switching circuit.

FIG. 2 is a circuit diagram of a switching circuit according to an embodiment.

FIG. 3 is a diagram for explaining transition from a high output state to a high impedance state in a source mode based on a first control sequence.

FIG. 4 is a diagram for explaining transition from a high output state to a high impedance state in a sink mode based on a second control sequence.

FIG. 5 is a diagram for explaining transition from a low output state to a high impedance state in a sink mode based on a third control sequence.

FIG. 6 is a diagram for explaining transition from a low output state to a high impedance state in a source mode based on a fourth control sequence.

FIG. 7 is a diagram for explaining transition from a high output state to a high impedance state based on a control sequence according to a first modification.

FIG. 8 is a diagram for explaining transition from a low output state to a high impedance state in a sink mode based on a control sequence according to a second modification.

FIG. 9 is a circuit diagram of a motor driver according to an embodiment.

### DETAILED DESCRIPTION

### Overview of Embodiments

An overview of several exemplary embodiments of the present disclosure is described. As a preface to the detailed description provided below, this overview provides a simplified explanation of several concepts of one or more embodiments for the purpose of a basic understanding of the embodiments and does not limit the scope of the invention or the disclosure. For convenience, the term “an embodiment” may be used herein to refer to a single embodiment (example or modification) or multiple embodiments (examples or modifications) disclosed in the present specification.

This overview is not a comprehensive summary of all conceivable embodiments and is not intended to identify essential elements of all the embodiments or to delineate the scope of some or all aspects. Its sole purpose is to present some concepts of one or more embodiments in a simplified form as a preface to the more detailed description to be presented later.

A gate driver circuit according to an embodiment drives a high-side transistor and a low-side transistor forming a switching circuit. The gate driver circuit includes: a high-side driver configured to drive the high-side transistor, a driving capability of the high-side driver being switchable in multiple stages including a first capability, a second capability lower than the first capability, and a third capability higher than the first capability; a low-side driver configured to drive the low-side transistor; a first output sensor configured to compare an output voltage of the switching circuit with a first threshold voltage, and to generate a first output detection signal that takes a first level when the output voltage is higher and takes a second level when the output voltage is lower; a high-side gate sensor configured to assert a high-side OFF detection signal when a gate-source voltage of the high-side transistor becomes lower than a predetermined voltage level; and a control circuit configured to switch between a high output state in which the high-side transistor is ON and the low-side transistor is OFF, a low output state in which the high-side transistor is OFF and the low-side transistor is ON, and a high impedance state in which the high-side transistor and the low-side transistor are OFF, by controlling the high-side driver and the low-side driver. When the switching circuit operates in a source mode, the control circuit is configured to: (i) enter a first period when an instruction for transition from the high output state to the high impedance state occurs, and set the driving capability of the high-side driver to the first capability in the first period; (ii) enter a second period when the first output detection signal changes to the second level in the first period, and set the driving capability of the high-side driver to the second capability in the second period; and (iii) enter a third period when assertion of the high-side OFF detection signal occurs in the second period, and set the driving capability of the high-side driver to the third capability in the third period.

When transitioning from the high output state to the high impedance state, if the high-side transistor is instantaneously turned off with a strong capability, there is a possibility that EMI (Electro Magnetic Interference) may deteriorate. In the above-described configuration and sequence, a period in which a drain current flowing through the high-side transistor (hereinafter referred to as a “high-side current”) is substantially constant becomes the first period, and a period in which the high-side current changes becomes the second period. In the first period, by turning off the high-side transistor with the first capability, the turn-off time can be shortened and power consumption can be reduced. In addition, in the second period, by weakening the driving capability to the second capability, the rate of change of the high-side current is reduced, and EMI can be suppressed. Moreover, a negative voltage generated at the output can be suppressed. Since EMI is unlikely to occur after the high-side transistor is turned off, the control circuit waits for the assertion of the high-side OFF detection signal and then increases the driving capability to the third capability to fix the high-side transistor in the OFF state. According to this turn-off sequence of the high-side transistor, transition from the high output state to the high impedance state can be performed in a short time while suppressing the occurrence of EMI.

In an embodiment, the gate driver circuit may further include a second output sensor configured to compare the output voltage of the switching circuit with a second threshold voltage determined to be higher than the first threshold voltage, and to generate a second output detection signal that takes a first level when the output voltage is higher and takes a second level when the output voltage is lower. The high-side driver may be configured such that the first capability is switchable in two levels. When the switching circuit operates in the source mode, the control circuit may be configured to: (i-a) set the driving capability of the high-side driver to a higher level of the first capability when the second output detection signal is at the first level in the first period; and (i-b) set the driving capability of the high-side driver to a lower level of the first capability after the second output detection signal changes to the second level.

In the first period, where the high-side current is substantially constant, by selecting the higher level of the first capability for the driving capability of the high-side driver at the beginning and then switching to the lower level of the first capability partway through, the capability in the first half can be set higher compared to a case where the driving capability is kept fixed throughout the first period, thereby further shortening the turn-off time and reducing power consumption.

In an embodiment, when the switching circuit operates in a sink mode, the control circuit may be configured to enter the third period without passing through the second period if assertion of the high-side OFF detection signal occurs in the first period.

In an embodiment, the gate driver circuit may further include: a low-side gate sensor configured to assert a low-side OFF detection signal when a gate-source voltage of the low-side transistor becomes lower than a predetermined voltage level; and a second output sensor configured to compare the output voltage of the switching circuit with a second threshold voltage determined to be higher than the first threshold voltage, and to generate a second output detection signal that takes a first level when the output voltage is higher and takes a second level when the output voltage is lower. The low-side driver may be configured such that a driving capability is switchable in multiple stages including a fourth capability, a fifth capability lower than the fourth capability, and a sixth capability higher than the fourth capability. When the switching circuit operates in a sink mode, the control circuit may be configured to: (iv) enter a fourth period when an instruction for transition from the low output state to the high impedance state occurs, and set the driving capability of the low-side driver to the fourth capability in the fourth period; (v) enter a fifth period when the second output detection signal changes to the first level in the fourth period, and set the driving capability of the low-side driver to the fifth capability in the fifth period; and (vi) enter a sixth period when assertion of the low-side OFF detection signal occurs in the fifth period, and set the driving capability of the low-side driver to the sixth capability in the sixth period.

When transitioning from the low output state to the high impedance state, if the low-side transistor is instantaneously turned off with a strong capability, there is a possibility that EMI may deteriorate. In the above-described configuration and sequence, a period in which a drain current flowing through the low-side transistor (hereinafter referred to as a “low-side current”) is substantially constant becomes the fourth period, and a period in which the low-side current changes becomes the fifth period. In the fourth period, by turning off the low-side transistor with the fourth capability, the turn-off time can be shortened and power consumption can be reduced. In addition, in the fifth period, by weakening the driving capability to the fifth capability, the rate of change of the low-side current is reduced, and EMI can be suppressed. Moreover, an overvoltage generated at the output can be suppressed. Since EMI is unlikely to occur after the low-side transistor is turned off, the control circuit waits for the assertion of the low-side OFF detection signal and then increases the driving capability to the sixth capability to fix the low-side transistor in the OFF state. According to this turn-off sequence of the low-side transistor, transition from the low output state to the high impedance state can be performed in a short time while suppressing the occurrence of EMI.

In an embodiment, the low-side driver may be configured such that the fourth capability is switchable in two levels. When the switching circuit operates in the sink mode, the control circuit may be configured to: (iv-a) set the driving capability of the low-side driver to a higher level of the fourth capability when the first output detection signal is at the second level in the fourth period; and (iv-b) set the driving capability of the low-side driver to a lower level of the fourth capability after the first output detection signal changes to the first level.

In the fourth period, where the low-side current is substantially constant, by selecting the higher level of the fourth capability for the driving capability of the low-side driver at the beginning and then switching to the lower level of the fourth capability partway through, the capability in the first half can be set higher compared to a case where the driving capability is kept fixed throughout the fourth period, thereby further shortening the turn-off time and reducing power consumption.

In an embodiment, when the switching circuit operates in a source mode, the control circuit may be configured to enter the sixth period without passing through the fifth period if assertion of the low-side OFF detection signal occurs in the fourth period.

A gate driver circuit according to an embodiment includes: a high-side driver configured to drive a high-side transistor; a low-side driver configured to drive a low-side transistor, a driving capability of the low-side driver being switchable in multiple stages including a fourth capability, a fifth capability lower than the fourth capability, and a sixth capability higher than the fourth capability; a second output sensor configured to compare an output voltage of the switching circuit with a second threshold voltage, and to generate a second output detection signal that takes a first level when the output voltage is higher and takes a second level when the output voltage is lower; a low-side gate sensor configured to assert a low-side OFF detection signal when a gate-source voltage of the low-side transistor becomes lower than a predetermined voltage level; and a control circuit configured to switch between a high output state in which the high-side transistor is ON and the low-side transistor is OFF, a low output state in which the high-side transistor is OFF and the low-side transistor is ON, and a high impedance state in which the high-side transistor and the low-side transistor are OFF, by controlling the high-side driver and the low-side driver. When the switching circuit operates in a sink mode, the control circuit is configured to: (iv) enter a fourth period when an instruction for transition from the low output state to the high impedance state occurs, and set the driving capability of the low-side driver to the fourth capability in the fourth period; (v) enter a fifth period when the second output detection signal changes to the first level in the fourth period, and set the driving capability of the low-side driver to the fifth capability in the fifth period; and (vi) enter a sixth period when assertion of the low-side OFF detection signal occurs in the fifth period, and set the driving capability of the low-side driver to the sixth capability in the sixth period.

When transitioning from the low output state to the high impedance state, if the low-side transistor is instantaneously turned off with a strong capability, there is a possibility that EMI may deteriorate. In the above-described configuration and sequence, a period in which a drain current flowing through the low-side transistor (hereinafter referred to as a “low-side current”) is substantially constant becomes the fourth period, and a period in which the low-side current changes becomes the fifth period. In the fourth period, by turning off the low-side transistor with the fourth capability, the turn-off time can be shortened and power consumption can be reduced. In addition, in the fifth period, by weakening the driving capability to the fifth capability, the rate of change of the low-side current is reduced, and EMI can be suppressed. Moreover, an overvoltage generated at the output can be suppressed. Since EMI is unlikely to occur after the low-side transistor is turned off, the control circuit waits for the assertion of the low-side OFF detection signal and then increases the driving capability to the sixth capability to fix the low-side transistor in the OFF state. According to this turn-off sequence of the low-side transistor, transition from the low output state to the high impedance state can be performed in a short time while suppressing the occurrence of EMI.

In an embodiment, the gate driver circuit may further include a first output sensor configured to compare the output voltage of the switching circuit with a first threshold voltage determined to be lower than the second threshold voltage, and to generate a first output detection signal that takes a first level when the output voltage is higher and takes a second level when the output voltage is lower. The low-side driver may be configured such that the fourth capability is switchable in two levels. When the switching circuit operates in the sink mode, the control circuit may be configured to: (iv-a) set the driving capability of the low-side driver to a higher level of the fourth capability when the first output detection signal is at the second level in the fourth period; and (iv-b) set the driving capability of the low-side driver to a lower level of the fourth capability after the first output detection signal changes to the first level.

In the fourth period, where the current flowing through the low-side transistor is substantially constant, by selecting the higher level of the fourth capability for the driving capability of the low-side driver at the beginning and then switching to the lower level of the fourth capability partway through, the capability in the first half can be set higher compared to a case where the driving capability is kept fixed throughout the fourth period, thereby further shortening the turn-off time and reducing power consumption.

In an embodiment, when the switching circuit operates in a source mode, the control circuit may be configured to enter the sixth period without passing through the fifth period if assertion of the low-side OFF detection signal occurs in the fourth period.

In an embodiment, the gate driver circuit may be monolithically integrated on a single semiconductor substrate. The term “monolithically integrated” includes cases where all the constituent elements of the circuit are formed on the semiconductor substrate, or cases where the main constituent elements of the circuit are monolithically integrated, and some resistors, capacitors, or the like for adjusting circuit constants may be provided outside the semiconductor substrate. By integrating the circuit on a single chip, the circuit area can be reduced and the characteristics of the circuit elements can be kept uniform.

In an embodiment, a motor driver circuit may include a switching circuit including a high-side transistor and a low-side transistor, and any of the above-described gate driver circuits configured to drive the switching circuit.

In an embodiment, an electronic device may include a motor and any of the above-described motor driver devices configured to drive the motor.

Preferred embodiments will now be described with reference to the accompanying drawings. The same or equivalent constituent elements, members, and processes shown in each drawing are denoted by the same reference numerals, and redundant descriptions thereof will be omitted as appropriate. Furthermore, the embodiments are illustrative and do not limit the invention, and all features and combinations thereof described in the embodiments are not necessarily essential to the invention.

In the present specification, the state in which “a member A is connected to a member B” includes not only a case where the member A and the member B are physically and directly connected, but also a case where the member A and the member B are indirectly connected via another member that does not substantially affect the electrical connection state between them or does with not impair the functions or effects achieved by the coupling thereof.

Similarly, the state in which “a member C is provided between a member A and a member B” includes not only a case where the member A and the member C, or the member B and the member C are directly connected, but also a case where they are indirectly connected via another member that does not substantially affect the electrical connection state between them or does not impair the functions or effects achieved by the coupling thereof.

First, a problem that occurs when a power transistor is turned off in a switching circuit will be described.

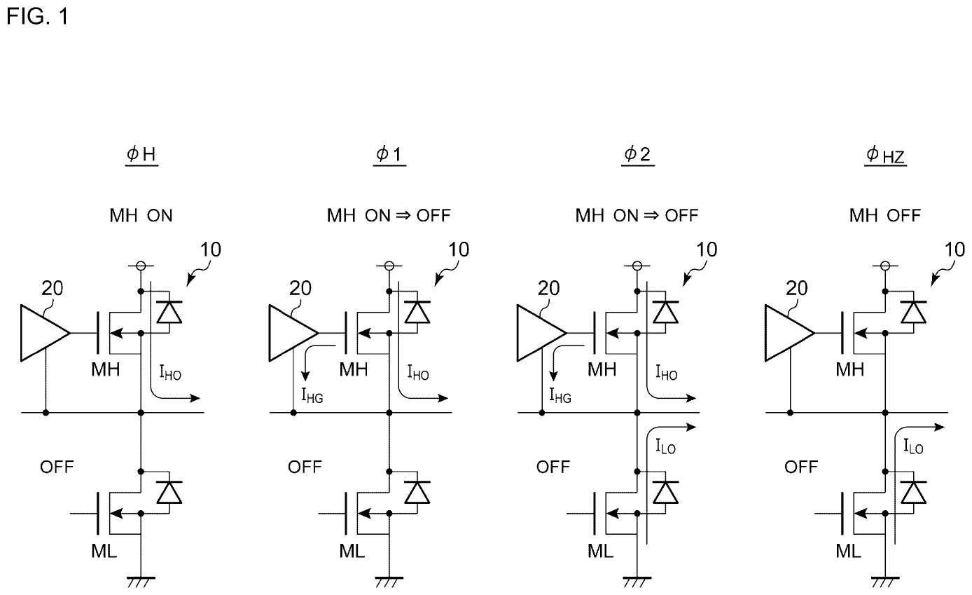

FIG. 1 is a circuit diagram illustrating switching of a switching circuit 10. The switching circuit 10 includes a high-side transistor MH and a low-side transistor ML connected in series between an input terminal and a ground terminal. The switching circuit 10 can take three states: a high output state φ_{H} in which the high-side transistor MH is ON and the low-side transistor ML is OFF; a low output state φ_{L} in which the high-side transistor MH is OFF and the low-side transistor ML is ON; and a high impedance state φ_{HZ} in which both the high-side transistor MH and the low-side transistor ML are OFF.

FIG. 1 illustrates a state in which the switching circuit 10 operating in a current source mode transitions from the high output state φ_{H} to the high impedance state φ_{HZ}. In the current source mode, a current I_{OUT} is supplied from the switching circuit 10 toward a load (not shown).

In the high output state φ_{H}, a high-side current I_{HO} flowing from a power supply line through the high-side transistor MH is supplied to the load as the output current I_{OUT}.

States φ₁ and φ₂ indicate a turn-off period of the high-side transistor MH. The high-side driver 20 draws a gate current I_{HG} from the gate of the high-side transistor MH to decrease the gate-source voltage of the high-side transistor MH over time. In the state φ₁, the load current is mainly a high-side current I_{HO} flowing through the high-side transistor MH. In the state φ₂, the load current is the sum of the high-side current I_{HO} flowing through the high-side transistor MH and a current I_{LO} flowing through a body diode of the low-side transistor ML.

In the high impedance state φ_{HZ}, both the high-side transistor MH and the low-side transistor ML are OFF, and the output current I_{OUT} is supplied from the body diode of the low-side transistor ML to the load.

In the period φ₁ of FIG. 1, the power consumption of the high-side transistor MH is I_{HO}×V_{DS(H)}. V_{DS(H)} is a drain-source voltage of the high-side transistor MH. If the turn-off speed of the high-side transistor MH is slow, the period during which the power consumption I_{HO}×V_{DS(H)} is large becomes longer, which increases the loss of the switching circuit and leads to larger heat generation. If the high-side transistor MH is turned off at high speed to reduce power consumption, the power consumption of the high-side transistor MH decreases, but the slope of the high-side current I_{HO} flowing through the high-side transistor MH in the state φ₂ becomes steeper, resulting in increased EMI. Furthermore, if the slope of the high-side current I_{HO} in the state φ₂ is steep, the output voltage V_{OUT} becomes a large negative voltage until the body diode of the low-side transistor ML conducts.

As described above, in the control in which the gate current I_{HG} is kept at a constant amount, there is a trade-off relationship between the power consumption of the high-side transistor MH and the EMI and the negative voltage at the output.

A gate driver circuit capable of suppressing EMI and negative voltage while reducing power consumption will be described below.

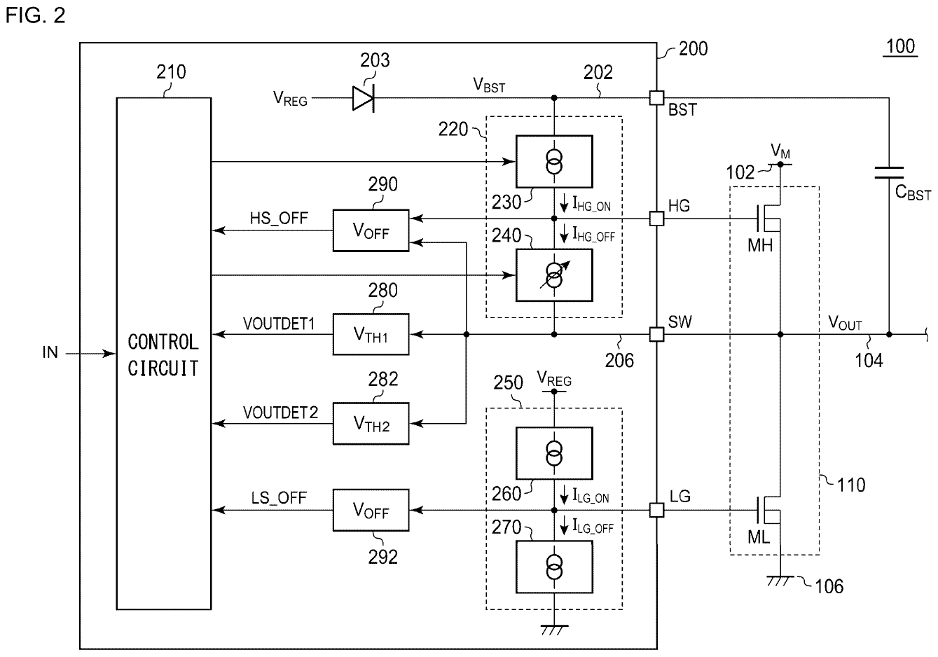

FIG. 2 is a circuit diagram of a switching circuit 100 according to an embodiment. The switching circuit 100 includes a bridge circuit 110 and a gate driver circuit 200. Although only a configuration for one phase of the switching circuit 100 is shown here, the switching circuit 100 may be a three-phase circuit or an H-bridge circuit.

The bridge circuit 110 includes a high-side transistor MH provided between a power supply line (input line) 102 and an output terminal (output line) 104, and a low-side transistor ML provided between the output line 104 and a ground line 106. An input voltage V_{M} is supplied to the input line 102. In the present embodiment, the high-side transistor MH and the low-side transistor ML are N-channel MOSFETs, and their respective body diodes also function as flywheel diodes.

The gate driver circuit 200 drives the high-side transistor MH and the low-side transistor ML of the bridge circuit 110 in response to an input signal IN. The input signal IN instructs one of three states: a high output state φ_{H} in which the high-side transistor MH is ON and the low-side transistor ML is OFF; a low output state φ_{L} in which the high-side transistor MH is OFF and the low-side transistor ML is ON; and a high impedance state φ_{HZ} in which both the high-side transistor MH and the low-side transistor ML are OFF.

A bootstrap capacitor CBST is connected between a bootstrap pin BST and the output line 104. A high-side gate pin HG is connected to the gate of the high-side transistor MH. A switching pin SW is connected to the source of the high-side transistor MH and the drain of the low-side transistor ML. A low-side gate pin LG is connected to the gate of the low-side transistor ML.

A bootstrap line 202 is connected to the bootstrap pin BST. A constant voltage V_{REG} is applied to the bootstrap line 202 via a rectifying element 203. The rectifying element 203 and the bootstrap capacitor CBST form a bootstrap circuit and maintain a voltage VBST of the bootstrap line 202 at V_{OUT}+V_{REG}−V_{F}. V_{F} is a forward voltage of the rectifying element 203.

The gate driver circuit 200 includes a control circuit 210, a high-side driver 220, a low-side driver 250, a first output sensor 280, a second output sensor 282, a high-side OFF sensor 290, and a low-side OFF sensor 292, and is a functional IC integrated on a single semiconductor substrate.

The high-side driver 220 includes a turn-on circuit 230 and a turn-off circuit 240. The turn-on circuit 230 becomes active when the high-side transistor MH is turned on, and sources a gate current I_{HG_ON} to the gate of the high-side transistor MH. The gate capacitance of the high-side transistor MH is charged by the gate current I_{HG_ON}, and the gate-source voltage of the high-side transistor MH increases.

The turn-off circuit 240 becomes active when the high-side transistor MH is turned off and sinks a gate current I_{HG_OFF} from the gate of the high-side transistor MH. The gate capacitance of the high-side transistor MH is discharged by the gate current I_{HG_OFF}, and the gate-source voltage of the high-side transistor MH decreases.

The low-side driver 250 includes a turn-on circuit 260 and a turn-off circuit 270. The turn-on circuit 260 becomes active when the low-side transistor ML is turned on, and sources a gate current I_{LG_ON} to the gate of the low-side transistor ML. The gate capacitance of the low-side transistor ML is charged by the gate current I_{LG_ON}, increasing the gate-source voltage of the low-side transistor ML.

The turn-off circuit 270 becomes active when the low-side transistor ML is turned off, and sinks a gate current I_{LG_OFF} from the gate of the low-side transistor ML. The gate capacitance of the low-side transistor ML is discharged by the gate current I_{LG_OFF}, and the gate-source voltage of the low-side transistor ML decreases.

In FIG. 2, the turn-on circuit 230 and the turn-off circuit 240 of the high-side driver 220, and the turn-on circuit 260 and the turn-off circuit 270 of the low-side driver 250 are indicated by symbols of current sources, but their configurations are not particularly limited.

The turn-off circuit 240 of the high-side driver 220 is configured such that its capacity is switchable in at least three stages. In a configuration where the turn-off circuit 240 functions as a current source, the capacity can be understood as the amount of current that the turn-off circuit 240 sinks. In a configuration where the turn-off circuit 240 functions as a voltage source, the capacity can be understood as the output impedance of the turn-off circuit 240.

Similarly, the turn-off circuit 270 of the low-side driver 250 is configured such that its capacity is switchable in at least three stages. In a configuration where the turn-off circuit 270 functions as a current source, the capacity can be understood as the amount of current that the turn-off circuit 270 sinks. In a configuration where the turn-off circuit 270 functions as a voltage source, the capacity can be understood as the output impedance of the turn-off circuit 240.

The first output sensor 280 is connected to a switching line 206 and monitors the output voltage V_{OUT}. The first output sensor 280 compares the output voltage V_{OUT} with a first threshold voltage V_{TH1} and generates a first output detection signal VOUTDET1 that becomes a first level (one of high and low) when V_{OUT}>V_{TH1} and becomes a second level (the other of high and low) when V_{OUT}<V_{TH1}. The first threshold voltage V_{TH1} can be set near 0 V, and may be, for example, approximately 1 V.

The second output sensor 282 is connected to the switching line 206 and monitors the output voltage V_{OUT}. The second output sensor 282 asserts (e.g., high) a second output detection signal VOUTDET2 when the output voltage V_{OUT} exceeds a second threshold voltage V_{TH2}. The second threshold voltage V_{TH2} can be set near the input voltage V_{M}, and may be, for example, approximately (V_{M}−1 V).

The high-side OFF sensor 290 asserts (e.g., high) a high-side OFF detection signal HS_OFF when detecting that the high-side transistor MH is turned off. For example, the high-side OFF sensor 290 compares a gate-source voltage V_{HGS} of the high-side transistor MH with a predetermined threshold voltage V_{OFF} and asserts the high-side OFF detection signal HS_OFF when V_{HGS}<V_{OFF}.

The low-side OFF sensor 292 asserts (e.g., high) a low-side OFF detection signal LS_OFF when detecting that the low-side transistor ML is turned off. For example, the low-side OFF sensor 292 compares a gate-source voltage V_{LGS} of the low-side transistor ML with a predetermined threshold voltage V_{OFF} and asserts the low-side OFF detection signal LS_OFF when V_{LGS}<V_{OFF}.

A control sequence of the high-side driver 220 and the low-side driver 250 by the control circuit 210 will be described.

### Control Sequence 1

Control Sequence 1 relates to the transition from the high output state φ_{H} to the high impedance state φ_{HZ} in a source mode. In an operation mode (source mode) in which the output current I_{OUT} of the bridge circuit 110 flows out toward a load (not shown), when the input signal IN transitions from the high output state φ_{H} to the high impedance state φ_{HZ}, the control circuit 210 controls the turn-off circuit 240 of the high-side driver 220 as follows.
(i) When an instruction for transition from the high output state φ_{H} to the high impedance state φ_{HZ} occurs, the control circuit 210 transitions to a first period φ₁. In the first period φ₁, the control circuit 210 enables the turn-off circuit 240 of the high-side driver 220 by setting it to a first capacity and turns off the high-side transistor MH.
(ii) Then, when the first output detection signal VOUTDET1 is asserted in the first period φ₁, the control circuit 210 transitions to a second period φ₂. In the second period φ₂, the control circuit 210 sets the turn-off circuit 240 to a second capacity lower than the first capacity.
(iii) When the high-side OFF detection signal HS_OFF is asserted in the second period φ₂, the control circuit 210 transitions to a third period φ₃. In the third period φ₃, the control circuit 210 sets the capacity of the turn-off circuit 240 to a third capacity higher than the first capacity and fixes the high-side transistor MH in an OFF state.

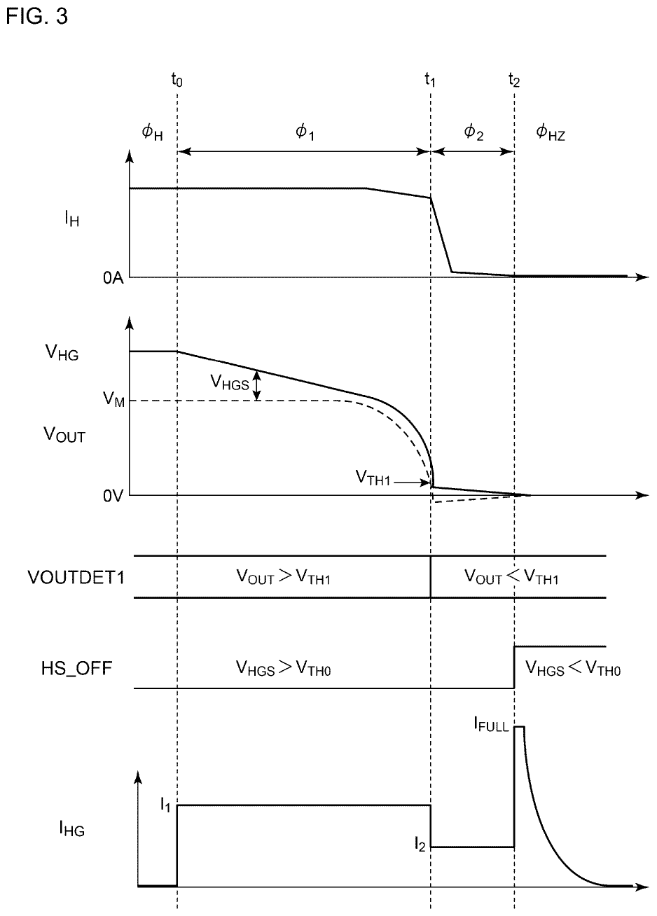

FIG. 3 is a diagram illustrating a transition from the high output state φ_{H} to the high impedance state φ_{HZ} in the source mode based on Control Sequence 1. I_{H} in the top row is a high-side current flowing through the high-side transistor MH. The dashed line in the second row represents the output voltage V_{OUT}, and the solid line represents the gate voltage V_{HG} of the high-side transistor MH. The third row shows the first output detection signal VOUTDET1, and the fourth row shows the high-side OFF detection signal HS_OFF. The bottom row shows the gate current I_{HG} that the high-side driver 220 sinks from the gate of the high-side transistor MH.

Before time t₀, the circuit is in the high output state, and the output voltage V_{OUT} is equal to the input voltage V_{M}.
(i) When a transition to the high impedance state φ_{HZ} is instructed at time t₀, the first period φ₁ begins. The first period φ₁ is a period during which the current I_{H} flowing through the high-side transistor MH can be regarded as substantially constant.

In the first period φ₁, the control circuit 210 enables the turn-off circuit 240 of the high-side driver 220 and sets it to a first capacity. The capacity of the high-side driver 220 has a positive correlation with the amount of gate current I_{H} sunk from the gate of the high-side transistor MH, and a current amount I₁ corresponds to the first capacity. As the first current I₁ is drawn from the gate of the high-side transistor MH, the gate-source voltage V_{HGS} of the high-side transistor MH decreases. The gate-source voltage V_{HGS} is the difference between the gate voltage V_{HG} and the source voltage (i.e., the output voltage V_{OUT}).

When the gate-source voltage V_{HGS} becomes low and the impedance of the high-side transistor MH becomes high, the output voltage V_{OUT} begins to decrease. When the output voltage V_{OUT} decreases to the first threshold voltage V_{TH1} near 0 V at time t₁, the first output detection signal VOUTDET1 changes to the second level (V_{OUT}<V_{TH1}), and the operation shifts to the second period φ₂. The second period φ₂ is a section in which the high-side current I_{H} changes significantly.
(ii) In the second period φ₂, the control circuit 210 sets the turn-off circuit 240 to a second capacity lower than the first capacity. By reducing it to the second capacity, the gate current I_{HG} decreases to a second current amount I₂. After time t₁, the gate-source voltage V_{HGS} of the high-side transistor MH continues to decrease further.

At time t₂, when the gate-source voltage V_{HGS} of the high-side transistor MH becomes lower than a voltage level V_{TH0} defined near the gate threshold V_{GS(th)} of the MOSFET—that is, when the high-side transistor MH turns off—the high-side OFF detection signal HS_OFF is asserted, and the operation transitions to the third period. The third period is the high impedance state φ_{HZ}.

In the high impedance state φ_{HZ}, the control circuit 210 sets the capacity of the turn-off circuit 240 to a third capacity higher than the first capacity and fixes the high-side transistor MH in the OFF state. When the turn-off circuit 240 is set to the third capacity, a current I_{FULL} is sunk from the gate of the high-side transistor MH, the charge of the gate capacitance is discharged, and the gate-source voltage V_{HGS} of the high-side transistor MH is fixed to zero.

The above is the operation of the gate driver circuit 200.

When transitioning from the high output state φ_{H} to the high impedance state φ_{HZ}, if the high-side transistor MH is instantaneously turned off with a strong capacity (the current I_{FULL} in FIG. 3) from the beginning, there is a risk that EMI will deteriorate.

By performing the control sequence 1 described above, the interval during which the high-side current I_{H} flowing through the high-side transistor MH is substantially constant becomes the first period φ₁, and the interval during which the high-side current I_{H} changes becomes the second period φ₂. In the first period φ₁, by turning off the high-side transistor MH with a relatively high first capacity, the turn-off time can be shortened and power consumption can be reduced. Further, in the second period φ₂, by weakening the driving capacity to the second capacity, the rate of change of the high-side current I_{H} is reduced and the slope is made gradual, thereby suppressing EMI. In addition, overvoltage occurring at the output can be suppressed.

Since EMI is unlikely to occur after the low-side transistor ML is turned off, the system waits for the assertion of the high-side OFF detection signal HS_OFF and then increases the driving capacity to the third capacity to fix the high-side transistor in the OFF state. According to this control sequence 1, it is possible to transition from the high output state to the high impedance state in a short time while suppressing the occurrence of EMI.

### Control Sequence 2

Control Sequence 2 relates to the transition from the high output state φ_{H} to the high impedance state φ_{HZ} in a sink mode. When the switching circuit 100 operates in the sink mode, if the high-side OFF detection signal HS_OFF is asserted in the first period φ₁, the control circuit 210 transitions to the third period φ_{HZ} without passing through the second period φ₂ and sets the driving capacity of the turn-off circuit 230 to the third capacity.

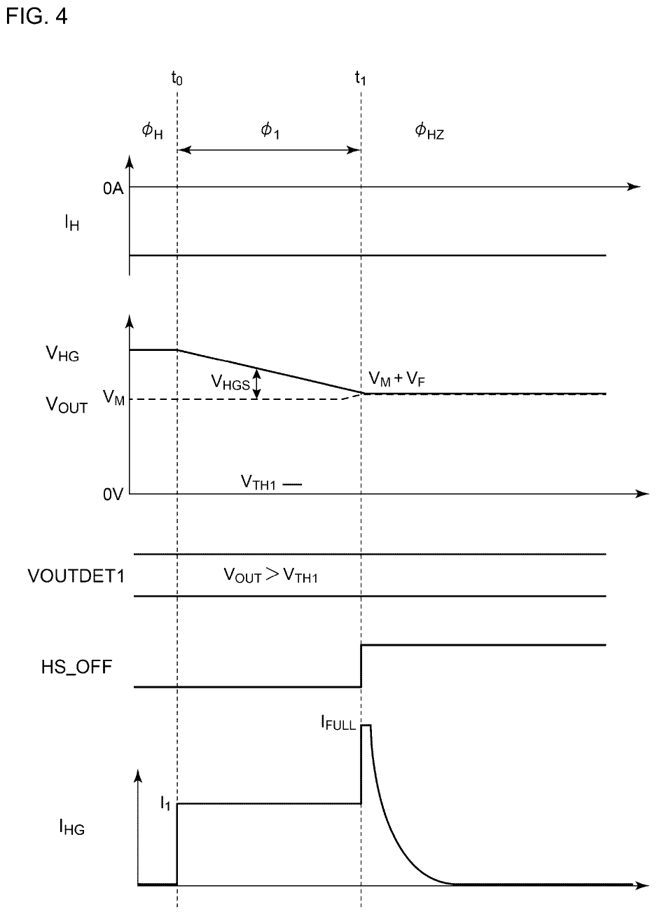

FIG. 4 is a diagram illustrating a transition from the high output state φ_{H} to the high impedance state φ_{HZ} in the sink mode based on Control Sequence 2.

Before time t₀, the circuit is in the high output state, and the output voltage V_{OUT} is equal to the input voltage V_{M}. In the sink mode, the high-side current I_{H} flowing through the high-side transistor MH is a negative current, flowing from the source toward the drain.
(i) When a transition to the high impedance state φ_{HZ} is instructed at time t₀, the first period φ₁ begins. The first period φ₁ is a period during which the current I_{H} flowing through the high-side transistor MH can be regarded as substantially constant.

In the first period φ₁, the control circuit 210 enables the turn-off circuit 240 of the high-side driver 220 and sets it to a first capacity. The capacity of the high-side driver 220 can be understood as the amount of gate current I_{H} sunk from the gate of the high-side transistor MH, and a current amount I₁ corresponds to the first capacity. As the first current I₁ is drawn from the gate of the high-side transistor MH, the gate-source voltage V_{HGS} of the high-side transistor MH decreases. The gate-source voltage V_{HGS} is the difference between the gate voltage V_{HG} and the source voltage (i.e., the output voltage V_{OUT}).

When the gate-source voltage V_{HGS} becomes low and the impedance of the high-side transistor MH becomes high, the high-side current I_{H} begins to flow through the body diode (parasitic diode) instead of the channel of the high-side transistor MH. As a result, the output voltage V_{OUT} increases toward V_{M}+V_{F}. V_{F} is the forward voltage of the body diode.

Then, when the gate-source voltage V_{HGS} of the high-side transistor MH becomes lower than the voltage level V_{TH0}, the high-side OFF detection signal HS_OFF is asserted, and the third period (high impedance state φ_{HZ}) begins.

In the high impedance state φ_{HZ}, the control circuit 210 sets the capacity of the turn-off circuit 240 to a third capacity higher than the first capacity, and fixes the high-side transistor MH in the OFF state. When the turn-off circuit 240 is set to the third capacity, the current I_{FULL} is sunk from the gate of the high-side transistor MH, the charge of the gate capacitance is discharged, and the gate-source voltage V_{HGS} of the high-side transistor MH is fixed to zero.

In the sink mode, a change in the high-side current I_{H} such as that in the source mode does not occur. Therefore, by driving the high-side transistor MH fixed at the first capacity, the high-side transistor MH can be turned off in a short time without generating EMI.

### Control Sequence 3

Control Sequence 3 relates to the transition from the low output state φ_{L} to the high impedance state φ_{HZ} in the sink mode.

When the switching circuit 100 operates in the sink mode and the input signal IN transitions from the low output state φ_{L} to the high impedance state φ_{HZ}, the control circuit 210 controls the turn-off circuit 270 of the low-side driver 250 as follows.
(iv) When an instruction for transition from the low output state φ_{L} to the high impedance state φ_{HZ} occurs, the control circuit 210 transitions to a fourth period φ₄. In the fourth period φ₄, the control circuit 210 sets the driving capacity of the turn-off circuit 270 of the low-side driver 250 to a fourth capacity. When the second output detection signal VOUTDET2 changes to the first level in the fourth period φ₄, the operation transitions to a fifth period φ₅.
(v) In the fifth period φ₅, the control circuit 210 sets the driving capacity of the turn-off circuit 270 of the low-side driver 250 to a fifth capacity. When the low-side OFF detection signal LS_OFF is asserted in the fifth period φ₅, the operation transitions to a sixth period.
(vi) In the sixth period, the control circuit 210 sets the driving capacity of the turn-off circuit 270 of the low-side driver 250 to a sixth capacity.

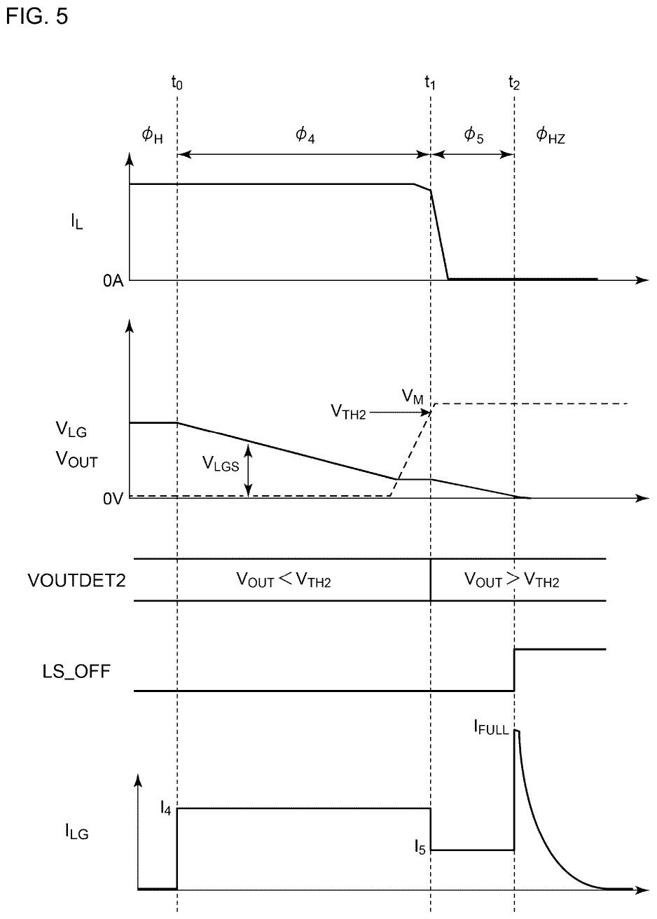

FIG. 5 is a diagram illustrating a transition from the low output state φ_{L} to the high impedance state φ_{HZ} in the sink mode based on Control Sequence 3. I_{L} in the top row is a low-side current flowing through the low-side transistor ML. The dashed line in the second row represents the output voltage V_{OUT}, and the solid line represents the gate voltage V_{LG} of the low-side transistor ML. The third row shows the second output detection signal VOUTDET2, and the fourth row shows the low-side OFF detection signal LS_OFF. The bottom row shows the gate current I_{LG} that the low-side driver 250 sinks from the gate of the low-side transistor ML.

Before time t₀, the circuit is in the low output state, and the output voltage V_{OUT} is 0 V. In the sink mode, a low-side current I_{L} flows from the drain toward the source of the low-side transistor ML.
(iv) When a transition to the high impedance state φ_{HZ} is instructed at time t₀, the fourth period φ₄ begins. The fourth period φ₄ is a period during which the current I_{L} flowing through the low-side transistor ML can be regarded as substantially constant.

In the fourth period φ₄, the control circuit 210 enables the turn-off circuit 270 of the low-side driver 250 and sets it to a fourth capacity. The capacity of the low-side driver 250 has a positive correlation with the amount of gate current I_{LG} sunk from the gate of the low-side transistor ML, and a current amount I₄ corresponds to the fourth capacity. As the fourth current I₄ is drawn from the gate of the low-side transistor ML, the gate voltage V_{LG} of the low-side transistor ML decreases. Since the source of the low-side transistor ML is grounded, the gate voltage V_{LG} of the low-side transistor ML is equal to the gate-source voltage V_{LGS}.

When the gate-source voltage V_{LGS} becomes low and the impedance of the low-side transistor ML becomes high, the output voltage V_{OUT} begins to increase. When the output voltage V_{OUT} increases to the second threshold voltage V_{TH2} near the input voltage V_{M} at time t₁, the second output detection signal VOUTDET2 changes to the first level (V_{OUT}>V_{TH2}), and the operation transitions to the fifth period φ₅. The fifth period φ₅ is a section in which the low-side current I_{L} changes significantly.
(v) In the fifth period φ₅, the control circuit 210 sets the turn-off circuit 270 to a fifth capacity lower than the fourth capacity. By reducing it to the fifth capacity, the gate current I_{LG} decreases to a fifth current amount I₅. After time t₁, the gate-source voltage V_{LGS} of the low-side transistor ML continues to decrease further.

At time t₂, when the gate-source voltage V_{LGS} of the low-side transistor ML becomes lower than a voltage level V_{TH0} defined near the gate threshold V_{GS(th)} of the MOSFET—that is, when the low-side transistor ML turns off—the low-side OFF detection signal LS_OFF is asserted, and the operation transitions to the sixth period. The sixth period is the high impedance state φ_{HZ}.
(vi) In the high impedance state φ_{HZ}, the control circuit 210 sets the capacity of the turn-off circuit 270 to a sixth capacity higher than the fourth capacity and fixes the low-side transistor ML in the OFF state. When the turn-off circuit 270 is set to the sixth capacity, a current I_{FULL} is sunk from the gate of the low-side transistor ML, the charge of the gate capacitance is discharged, and the gate-source voltage V_{LGS} of the low-side transistor ML is fixed to zero.

When transitioning from the low output state φ_{L} to the high impedance state φ_{HZ}, if the low-side transistor ML is instantaneously turned off with a strong capacity (the current I_{FULL} in FIG. 5) from the beginning, there is a risk that EMI will deteriorate.

By performing the control sequence 3, the interval during which the low-side current I_{L} flowing through the low-side transistor ML is substantially constant becomes the fourth period φ₄, and the interval during which the low-side current I_{L} changes becomes the fifth period φ₅. In the fourth period φ₄, by turning off the low-side transistor ML with a relatively high fourth capacity, the turn-off time can be shortened and power consumption can be reduced. Further, in the second period φ₅, by weakening the driving capacity to the fifth capacity, the rate of change of the low-side current I_{L} is reduced and the slope is made gradual, thereby suppressing EMI. In addition, negative voltage occurring at the output can be suppressed.

Since EMI is unlikely to occur after the low-side transistor ML is turned off, the system waits for the assertion of the low-side OFF detection signal LS_OFF and then increases the driving capacity to the sixth capacity to fix the low-side transistor ML in the OFF state. According to the control sequence 3, it is possible to transition from the low output state φ_{L} to the high impedance state φ_{HZ} in a short time while suppressing the occurrence of EMI.

### Control Sequence 4

Control Sequence 4 relates to the transition from the low output state φ_{L} to the high impedance state φ_{HZ} in the source mode. When the switching circuit 100 operates in the source mode, if the low-side OFF detection signal LS_OFF is asserted in the fourth period φ₄, the control circuit 210 transitions to the sixth period φ_{HZ} without passing through the fifth period φ₅ and sets the driving capacity of the turn-on circuit 230 to the sixth capacity.

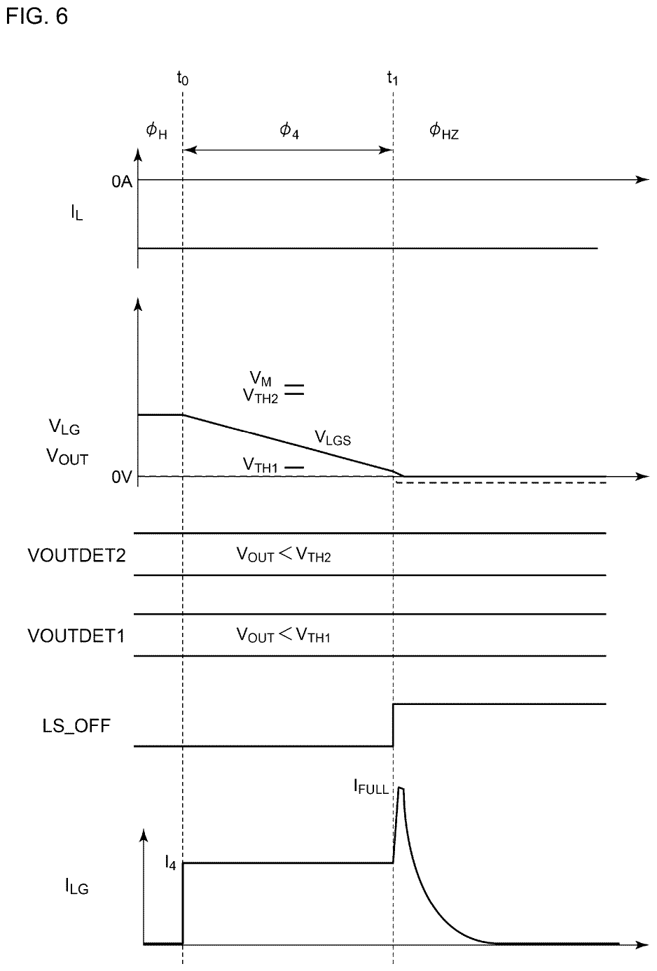

FIG. 6 is a diagram illustrating a transition from the low output state φ_{L} to the high impedance state φ_{HZ} in the source mode based on Control Sequence 4.

Before time t₀, the circuit is in the low output state, and the output voltage V_{OUT} is 0 V. In the source mode, the high-side current I_{H} is 0, and the low-side current I_{L} flows from the drain toward the source.
(iv) When a transition to the high impedance state φ_{HZ} is instructed at time t₀, the fourth period φ₄ begins. The fourth period φ₄ is a period during which the current I_{L} flowing through the low-side transistor ML can be regarded as substantially constant.

In the fourth period φ₄, the control circuit 210 enables the turn-off circuit 270 of the low-side driver 250 and sets it to a fourth capacity. The capacity of the low-side driver 250 can be understood as the amount of gate current I_{L} sunk from the gate of the low-side transistor ML, and a current amount I₄ corresponds to the fourth capacity. As the fourth current I₄ is drawn from the gate of the low-side transistor ML, the gate-source voltage V_{LGS} of the low-side transistor ML decreases.

When the gate-source voltage V_{LGS} becomes low and the impedance of the low-side transistor ML becomes high, the low-side current I_{L} begins to flow through the body diode (parasitic diode) instead of the channel of the low-side transistor ML. As a result, the output voltage V_{OUT} decreases toward −V_{F}. V_{F} is the forward voltage of the body diode.

Then, when the gate-source voltage V_{LGS} of the low-side transistor ML becomes lower than the voltage level V_{TH0}, the low-side OFF detection signal LS_OFF is asserted, and the sixth period (high impedance state φ_{HZ}) begins.

In the high impedance state φ_{HZ}, the control circuit 210 sets the capacity of the turn-off circuit 270 to a sixth capacity higher than the fourth capacity and fixes the low-side transistor ML in the OFF state. When the turn-off circuit 270 is set to the sixth capacity, a current I_{FULL} is sunk from the gate of the low-side transistor ML, the charge of the gate capacitance is discharged, and the gate-source voltage V_{LGS} of the low-side transistor ML is fixed to zero.

In the source mode, a change in the low-side current I_{L} such as that in the sink mode does not occur. Therefore, by driving the low-side transistor ML fixed at the fourth capacity, the low-side transistor ML can be turned off in a short time without generating EMI.

Next, a modification of the gate driver circuit 200 will be described.

### Modification 1

Modification 1 is a modification of Control Sequence 1, and the turn-off circuit 240 of the high-side driver 220 is configured such that its first capacity is switchable in two stages.
(i-a) When the switching circuit 100 operates in the source mode, the control circuit 210 sets the driving capacity of the high-side driver 220 to a high level of the first capacity during the first period φ₁ when the second output detection signal VOUTDET2 is at the first level. (i-b) After the second output detection signal VOUTDET2 changes to the second level (V_{OUT}<V_{TH2}), the control circuit 210 sets the driving capacity of the high-side driver 220 to a low level of the first capacity.

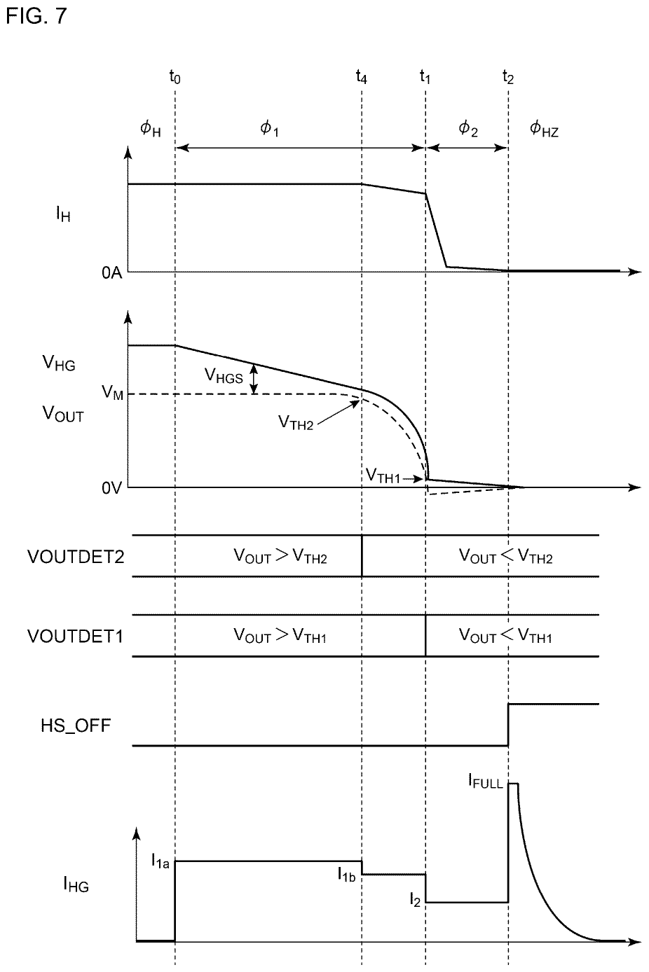

FIG. 7 is a diagram illustrating a transition from the high output state φ_{H} to the high impedance state φ_{HZ} based on the control sequence according to Modification 1. I_{H} in the top row is a high-side current flowing through the high-side transistor MH. The dashed line in the second row represents the output voltage V_{OUT}, and the solid line represents the gate voltage V_{HG} of the high-side transistor MH. The third row shows the second output detection signal VOUTDET2, and the fourth row shows the first output detection signal VOUTDET1. The fifth row shows the high-side OFF detection signal HS_OFF. The bottom row shows the gate current I_{HG} that the high-side driver 220 sinks from the gate of the high-side transistor MH.

Before time t₀, the circuit is in the high output state, and the output voltage V_{OUT} is equal to the input voltage V_{M}.
(i) When a transition to the high impedance state φ_{HZ} is instructed at time t₀, the first period φ₁ begins. The first period φ₁ is a period during which the current I_{H} flowing through the high-side transistor MH can be regarded as substantially constant.

In the first period φ₁, the control circuit 210 enables the turn-off circuit 240 of the high-side driver 220 and sets its driving capacity to the higher stage of the two stages of the first capacity. As a result, a current amount I₁ₐ is drawn from the gate of the high-side transistor MH, and the gate-source voltage V_{HGS} of the high-side transistor MH decreases.

When the gate-source voltage V_{HGS} becomes low and the impedance of the high-side transistor MH becomes high, the output voltage V_{OUT} begins to decrease.

At time t₄, when the output voltage V_{OUT} becomes lower than the second threshold voltage V_{TH2} near the input voltage V_{M} and the second output detection signal VOUTDET2 changes to the second level (V_{OUT}<V_{TH2}), the control circuit 210 sets the driving capacity of the turn-off circuit 240 of the high-side driver 220 to the lower stage of the two stages of the first capacity. As a result, a current amount I_{1b}, which is smaller than the current amount I₁ₐ, is drawn from the gate of the high-side transistor MH.

When the output voltage V_{OUT} decreases to the first threshold voltage V_{TH1} near 0 V at time t₁, the first output detection signal VOUTDET1 changes to the second level (V_{OUT}<V_{TH1}), and the operation transitions to the second period φ₂. The second period φ₂ is a section in which the high-side current I_{H} changes significantly.
(ii) In the second period φ₂, the control circuit 210 sets the turn-off circuit 240 to a second capacity lower than the first capacity. By reducing it to the second capacity, the gate current I_{HG} decreases to a second current amount I₂. After time t₁, the gate-source voltage V_{HGS} of the high-side transistor MH continues to decrease further.

At time t₂, when the gate-source voltage V_{HGS} of the high-side transistor MH becomes lower than the voltage level V_{TH0} defined near the gate threshold V_{GS(th)} of the MOSFET—that is, when the high-side transistor MH turns off—the high-side OFF detection signal HS_OFF is asserted, and the operation transitions to the third period. The third period is the high impedance state φ_{HZ}.

In the high impedance state φ_{HZ}, the control circuit 210 sets the capacity of the turn-off circuit 240 to a third capacity higher than the first capacity and fixes the high-side transistor MH in the OFF state. When the turn-off circuit 240 is set to the third capacity, the current I_{FULL} is sunk from the gate of the high-side transistor MH, the charge of the gate capacitance is discharged, and the gate-source voltage V_{HGS} of the high-side transistor MH is fixed to zero.

The above is the sequence according to Modification 1. In the first period φ₁ in which the current I_{H} flowing through the high-side transistor MH is substantially constant, by initially selecting the higher stage of the first capacity (I₁ₐ) for the driving capacity of the high-side driver 220 and switching to the lower stage of the first capacity (I_{1b}) midway, the driving capacity I₁ₐ in the first half can be set higher than the first capacity (current amount I₁) in Control Sequence 1 compared to a case where the driving capacity in the first period φ₁ is kept fixed, and the turn-off time can be further shortened and power consumption can be reduced.

### Modification 2

Modification 2 is a modification of Control Sequence 3, and the turn-off circuit 270 of the low-side driver 250 is configured such that its fourth capacity is switchable in two stages.
(iv-a) When the switching circuit 100 operates in the sink mode, the control circuit 210 sets the driving capacity of the low-side driver 250 to a high level of the fourth capacity during the fourth period φ₄ when the first output detection signal VOUTDET1 is at the second level (V_{OUT}<V_{TH1}). (i-b) After the first output detection signal VOUTDET1 changes to the first level (V_{OUT}>V_{TH1}), the control circuit 210 sets the driving capacity of the low-side driver 250 to a low level of the fourth capacity.

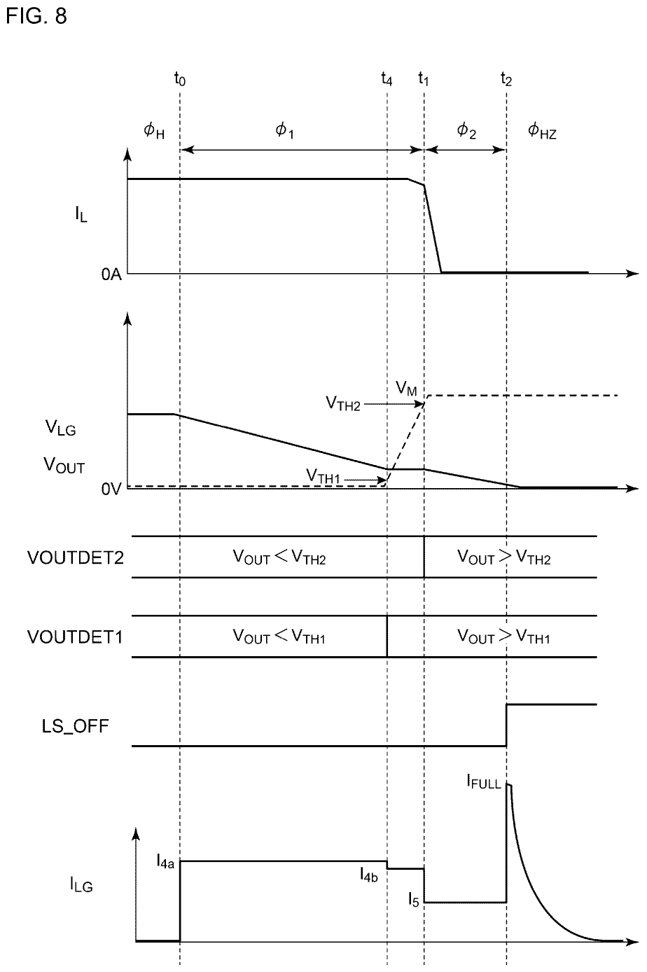

FIG. 8 is a diagram illustrating a transition from the low output state φ_{L} to the high impedance state φ_{HZ} in the sink mode based on the control sequence according to Modification 2. I_{L} in the top row is a low-side current flowing through the low-side transistor ML. The dashed line in the second row represents the output voltage V_{OUT}, and the solid line represents the gate voltage V_{LG} of the low-side transistor ML. The third row shows the second output detection signal VOUTDET2, and the fourth row shows the first output detection signal VOUTDET1. The fifth row shows the low-side OFF detection signal LS_OFF. The bottom row shows the gate current I_{LG} that the low-side driver 250 sinks from the gate of the low-side transistor ML.

Before time t₀, the circuit is in the low output state, and the output voltage V_{OUT} is 0 V. In the sink mode, a low-side current I_{L} flows from the drain toward the source of the low-side transistor ML.
(iv) When a transition to the high impedance state φ_{HZ} is instructed at time t₀, the fourth period φ₄ begins. The fourth period φ₄ is a period during which the current I_{L} flowing through the low-side transistor ML can be regarded as substantially constant.

In the fourth period φ₄, the control circuit 210 enables the turn-off circuit 270 of the low-side driver 250 and sets its driving capacity to the higher stage of the two stages of the fourth capacity. As a result, a fourth current I₄ₐ is drawn from the gate of the low-side transistor ML, and the gate voltage V_{LG} of the low-side transistor ML decreases.

When the gate-source voltage V_{LGS} becomes low and the impedance of the low-side transistor ML becomes high, the output voltage V_{OUT} begins to increase. When the output voltage V_{OUT} exceeds the first threshold voltage V_{TH1} at time t₄, the first output detection signal VOUTDET1 changes to the first level (V_{OUT}>V_{TH1}). In response to the change in the first output detection signal VOUTDET1, the control circuit 210 switches the driving capacity of the turn-off circuit 270 of the low-side driver 250 to the lower stage of the two stages of the fourth capacity.

When the output voltage rises to the second threshold voltage V_{TH2} near the input voltage V_{M} at time t₁, the second output detection signal VOUTDET2 changes to the first level, and the operation transitions to the fifth period φ₅. The fifth period φ₅ is a section in which the low-side current I_{L} changes significantly.
(v) In the fifth period φ₅, the control circuit 210 sets the turn-off circuit 270 to a fifth capacity lower than the fourth capacity. By reducing it to the fifth capacity, the gate current I_{LG} decreases to a fifth current amount I₅. After time t₁, the gate-source voltage V_{LGS} of the low-side transistor ML continues to decrease further.

At time t₂, when the gate-source voltage V_{LGS} of the low-side transistor ML becomes lower than the voltage level V_{TH0} defined near the gate threshold V_{GS(th)} of the MOSFET—that is, when the low-side transistor ML turns off—the low-side OFF detection signal LS_OFF is asserted, and the operation transitions to the sixth period. The sixth period is the high impedance state φ_{HZ}.
(vi) In the high impedance state φ_{HZ}, the control circuit 210 sets the capacity of the turn-off circuit 270 to a sixth capacity higher than the fourth capacity and fixes the low-side transistor ML in the OFF state. When the turn-off circuit 270 is set to the sixth capacity, a current I_{FULL} is sunk from the gate of the low-side transistor ML, the charge of the gate capacitance is discharged, and the gate-source voltage V_{LGS} of the low-side transistor ML is fixed to zero.

The above is the sequence according to Modification 2. In the fourth period φ₄ in which the current I_{L} flowing through the low-side transistor ML is substantially constant, by initially selecting the higher stage of the fourth capacity (I₄ₐ) for the driving capacity of the low-side driver 250 and switching to the lower stage of the fourth capacity (I_{4b}) midway, the driving capacity I₄ₐ in the first half can be set higher than the fourth capacity (current amount I₄) in Control Sequence 3 compared to a case where the driving capacity in the fourth period φ₄ is kept fixed, and the turn-off time can be further shortened and power consumption can be reduced.

### Applications

Next, applications of the switching circuit 100 will be described. The switching circuit 100 can be suitably used for a motor drive circuit.

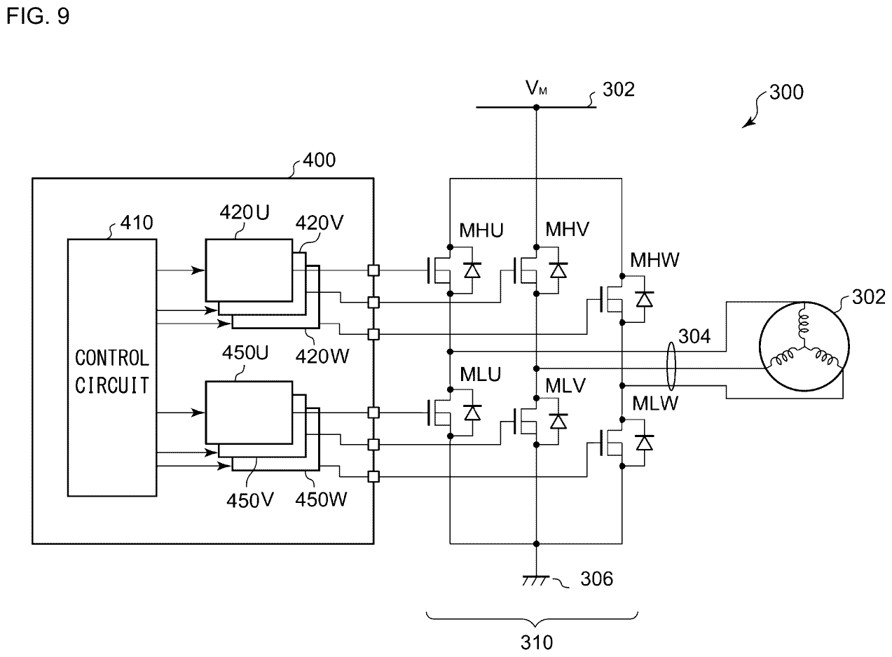

FIG. 9 is a circuit diagram of a motor drive device 300 according to an embodiment. The motor drive device 300 drives a three-phase motor 302, which is a load, and controls a rotation state.

The motor drive device 300 includes a bridge circuit 310 and a gate driver circuit 400. The bridge circuit 310 is a three-phase inverter and has U-phase, V-phase, and W-phase legs, and each phase leg includes a high-side transistor MH and a low-side transistor ML.

The gate driver circuit 400 includes a control circuit 410, high-side drivers 420U to 420W, and low-side drivers 450U to 450W. The control circuit 410 generates control signals indicating states of six arms constituting the bridge circuit 310 based on a state of the three-phase motor 302, which is the load.

The high-side drivers 420U to 420W are configured with the architecture of the high-side driver 220 described above. Further, the low-side drivers 450U to 450W are configured with the architecture of the low-side driver 250 described above.

Although a three-phase motor is used as an example here, a single-phase motor may be used. In this case, the bridge circuit 310 becomes an H-bridge circuit.

Next, applications of the motor drive device 300 will be described. The motor drive device 300 can be used for controlling a spindle motor of a hard disk or a lens-driving motor of an imaging device. Alternatively, it can be used for driving a motor for driving a head of a printer or a motor for feeding paper. Alternatively, the motor drive device 300 can be used for driving motors of electric vehicles, hybrid vehicles, and the like.

The embodiments are exemplary, and it is understood by those skilled in the art that various modifications are possible in the combination of each constituent element and each processing process, and that such modifications are also within the scope of the present disclosure. These modifications will be described below.

### Modification 1

In the embodiment, the bridge circuit 110 is configured with discrete components, but the present invention is not limited thereto, and the bridge circuit 110 may be integrated into the gate driver circuit 200.

### Modification 2

The upper arm 112 and the lower arm 114 may be configured with IGBTs (Insulated Gate Bipolar Transistors).

### Modification 3

The application of the switching circuit 100 is not limited to the motor drive device 300. For example, the switching circuit 100 can be suitably used for switching regulators (DC/DC converters), various power conversion devices (inverters and converters), discharge lamp lighting inverters, digital audio amplifiers, and the like. Therefore, the switching circuit 100 can be used for consumer equipment including electronic devices and home appliances, automobiles and vehicle-mounted parts, industrial vehicles, and industrial machinery.

The embodiments described using specific terms merely illustrate the principles and applications of the present disclosure, and many modifications and changes in arrangement are permitted in the embodiments without departing from the spirit of the present disclosure defined in the claims.

### Supplementary Notes

The following technologies are disclosed in the present specification.
Item 1. A gate driver circuit for driving a high-side transistor and a low-side transistor forming a switching circuit, the gate driver circuit comprising:
a high-side driver configured to drive the high-side transistor, a driving capability of the high-side driver being switchable in multiple stages including a first capability, a second capability lower than the first capability, and a third capability higher than the first capability;
a low-side driver configured to drive the low-side transistor;
a first output sensor configured to compare an output voltage of the switching circuit with a first threshold voltage, and to generate a first output detection signal that takes a first level when the output voltage is higher and takes a second level when the output voltage is lower;
a high-side gate sensor configured to assert a high-side OFF detection signal when a gate-source voltage of the high-side transistor becomes lower than a predetermined voltage level; and
a control circuit configured to switch between a high output state in which the high-side transistor is ON and the low-side transistor is OFF, a low output state in which the high-side transistor is OFF and the low-side transistor is ON, and a high impedance state in which the high-side transistor and the low-side transistor are OFF, by controlling the high-side driver and the low-side driver,
wherein the control circuit is configured to, when the switching circuit operates in a source mode:
(i) enter a first period when an instruction for transition from the high output state to the high impedance state occurs, and set the driving capability of the high-side driver to the first capability in the first period;
(ii) enter a second period when the first output detection signal changes to the second level in the first period, and set the driving capability of the high-side driver to the second capability in the second period; and
(iii) enter a third period when assertion of the high-side OFF detection signal occurs in the second period and set the driving capability of the high-side driver to the third capability in the third period.
Item 2. The gate driver circuit according to Item 1, further comprising:
a second output sensor configured to compare the output voltage of the switching circuit with a second threshold voltage determined to be higher than the first threshold voltage, and to generate a second output detection signal that takes a first level when the output voltage is higher and takes a second level when the output voltage is lower,
wherein the driving capability of the high-side driver is switchable in two levels within the first capability, and
wherein the control circuit is configured to, when the switching circuit operates in the source mode:
(i-a) set the driving capability of the high-side driver to a higher level of the first capability when the second output detection signal is at the first level in the first period; and
(ii-b) set the driving capability of the high-side driver to a lower level of the first capability after the second output detection signal changes to the second level.
Item 3. The gate driver circuit according to Item 1,
wherein the control circuit is configured to, when the switching circuit operates in a sink mode, enter the third period when assertion of the high-side OFF detection signal occurs in the first period, without passing through the second period.
Item 4. The gate driver circuit according to Item 1, further comprising:
a low-side gate sensor configured to assert a low-side OFF detection signal when a gate-source voltage of the low-side transistor becomes lower than a predetermined voltage level; and
a second output sensor configured to compare the output voltage of the switching circuit with a second threshold voltage determined to be higher than the first threshold voltage, and to generate a second output detection signal that takes a first level when the output voltage is higher and takes a second level when the output voltage is lower,
wherein a driving capability of the low-side driver is switchable in multiple stages including a fourth capability, a fifth capability lower than the fourth capability, and a sixth capability higher than the fourth capability, and
wherein the control circuit is configured to, when the switching circuit operates in a sink mode:
(iv) enter a fourth period when an instruction for transition from the low output state to the high impedance state occurs, and set the driving capability of the low-side driver to the fourth capability in the fourth period;
(v) enter a fifth period when the second output detection signal changes to the first level in the fourth period, and set the driving capability of the low-side driver to the fifth capability in the fifth period; and
(vi) enter a sixth period when assertion of the low-side OFF detection signal occurs in the fifth period and set the driving capability of the low-side driver to the sixth capability in the sixth period.
Item 5. The gate driver circuit according to Item 4,
wherein the driving capability of the low-side driver is switchable in two levels within the fourth capability, and
wherein the control circuit is configured to, when the switching circuit operates in the sink mode:
(iv-a) set the driving capability of the low-side driver to a higher level of the fourth capability when the first output detection signal is at the second level in the fourth period; and
(iv-b) set the driving capability of the low-side driver to a lower level of the fourth capability after the first output detection signal changes to the first level.
Item 6. The gate driver circuit according to Item 4,
wherein the control circuit is configured to, when the switching circuit operates in a source mode:
enter the sixth period when assertion of the low-side OFF detection signal occurs in the fourth period, without passing through the fifth period.
Item 7. A gate driver circuit for driving a high-side transistor and a low-side transistor forming a switching circuit, the gate driver circuit comprising:
a high-side driver configured to drive the high-side transistor;
a low-side driver configured to drive the low-side transistor, a driving capability of the low-side driver being switchable in multiple stages including a fourth capability, a fifth capability lower than the fourth capability, and a sixth capability higher than the fourth capability;
a second output sensor configured to compare an output voltage of the switching circuit with a second threshold voltage, and to generate a second output detection signal that takes a first level when the output voltage is higher and takes a second level when the output voltage is lower;
a low-side gate sensor configured to assert a low-side OFF detection signal when a gate-source voltage of the low-side transistor becomes lower than a predetermined voltage level; and
a control circuit configured to switch between a high output state in which the high-side transistor is ON and the low-side transistor is OFF, a low output state in which the high-side transistor is OFF and the low-side transistor is ON, and a high impedance state in which the high-side transistor and the low-side transistor are OFF, by controlling the high-side driver and the low-side driver,
wherein the control circuit is configured to, when the switching circuit operates in a sink mode:
(iv) enter a fourth period when an instruction for transition from the low output state to the high impedance state occurs, and set the driving capability of the low-side driver to the fourth capability in the fourth period;
(v) enter a fifth period when the second output detection signal changes to the first level in the fourth period, and set the driving capability of the low-side driver to the fifth capability in the fifth period; and
(vi) enter a sixth period when assertion of the low-side OFF detection signal occurs in the fifth period and set the driving capability of the low-side driver to the sixth capability in the sixth period.
Item 8. The gate driver circuit according to Item 7, further comprising:
a first output sensor configured to compare the output voltage of the switching circuit with a first threshold voltage determined to be lower than the second threshold voltage, and to generate a first output detection signal that takes a first level when the output voltage is higher and takes a second level when the output voltage is lower,
wherein the driving capability of the low-side driver is switchable in two levels within the fourth capability, and
wherein the control circuit is configured to, when the switching circuit operates in the sink mode:
(iv-a) set the driving capability of the low-side driver to a higher level of the fourth capability when the first output detection signal is at the second level in the fourth period; and
(iv-b) set the driving capability of the low-side driver to a lower level of the fourth capability after the first output detection signal changes to the first level.
Item 9. The gate driver circuit according to claim 7,
wherein the control circuit is configured to, when the switching circuit operates in a source mode:
enter the sixth period when assertion of the low-side OFF detection signal occurs in the fourth period, without passing through the fifth period.
Item 10. The gate driver circuit according to any one of Item 1 to Item 9, monolithically integrated on a single semiconductor substrate.
Item 11. A motor driver comprising:
a switching circuit including a high-side transistor and a low-side transistor; and
the gate driver circuit according to any one of Item 1 to Item 10, configured to drive the switching circuit.
Item 12. An electronic device comprising:
a motor; and
   the motor driver according to Item 11, configured to drive the motor.

What is claimed is:

1. A gate driver circuit for driving a high-side transistor and a low-side transistor forming a switching circuit, the gate driver circuit comprising:
a high-side driver configured to drive the high-side transistor, a driving capability of the high-side driver being switchable in multiple stages including a first capability, a second capability lower than the first capability, and a third capability higher than the first capability;
a low-side driver configured to drive the low-side transistor;
a first output sensor configured to compare an output voltage of the switching circuit with a first threshold voltage, and to generate a first output detection signal that takes a first level when the output voltage is higher and takes a second level when the output voltage is lower;
a high-side gate sensor configured to assert a high-side OFF detection signal when a gate-source voltage of the high-side transistor becomes lower than a predetermined voltage level; and
a control circuit configured to switch between a high output state in which the high-side transistor is ON and the low-side transistor is OFF, a low output state in which the high-side transistor is OFF and the low-side transistor is ON, and a high impedance state in which the high-side transistor and the low-side transistor are OFF, by controlling the high-side driver and the low-side driver,
wherein the control circuit is configured to, when the switching circuit operates in a source mode:
(i) enter a first period when an instruction for transition from the high output state to the high impedance state occurs, and set the driving capability of the high-side driver to the first capability in the first period;
(ii) enter a second period when the first output detection signal changes to the second level in the first period, and set the driving capability of the high-side driver to the second capability in the second period; and
(iii) enter a third period when assertion of the high-side OFF detection signal occurs in the second period, and set the driving capability of the high-side driver to the third capability in the third period.

2. The gate driver circuit according to claim 1, further comprising:
a second output sensor configured to compare the output voltage of the switching circuit with a second threshold voltage determined to be higher than the first threshold voltage, and to generate a second output detection signal that takes a first level when the output voltage is higher and takes a second level when the output voltage is lower,
wherein the driving capability of the high-side driver is switchable in two levels within the first capability, and
wherein the control circuit is configured to, when the switching circuit operates in the source mode:
(i-a) set the driving capability of the high-side driver to a higher level of the first capability when the second output detection signal is at the first level in the first period; and
(ii-b) set the driving capability of the high-side driver to a lower level of the first capability after the second output detection signal changes to the second level.

3. The gate driver circuit according to claim 1,
wherein the control circuit is configured to, when the switching circuit operates in a sink mode, enter the third period when assertion of the high-side OFF detection signal occurs in the first period, without passing through the second period.

4. The gate driver circuit according to claim 1, further comprising:
a low-side gate sensor configured to assert a low-side OFF detection signal when a gate-source voltage of the low-side transistor becomes lower than a predetermined voltage level; and
a second output sensor configured to compare the output voltage of the switching circuit with a second threshold voltage determined to be higher than the first threshold voltage, and to generate a second output detection signal that takes a first level when the output voltage is higher and takes a second level when the output voltage is lower,
wherein a driving capability of the low-side driver is switchable in multiple stages including a fourth capability, a fifth capability lower than the fourth capability, and a sixth capability higher than the fourth capability, and
wherein the control circuit is configured to, when the switching circuit operates in a sink mode:
(iv) enter a fourth period when an instruction for transition from the low output state to the high impedance state occurs, and set the driving capability of the low-side driver to the fourth capability in the fourth period;
(v) enter a fifth period when the second output detection signal changes to the first level in the fourth period, and set the driving capability of the low-side driver to the fifth capability in the fifth period; and
(vi) enter a sixth period when assertion of the low-side OFF detection signal occurs in the fifth period, and set the driving capability of the low-side driver to the sixth capability in the sixth period.

5. The gate driver circuit according to claim 4,
wherein the driving capability of the low-side driver is switchable in two levels within the fourth capability, and
wherein the control circuit is configured to, when the switching circuit operates in the sink mode:
(iv-a) set the driving capability of the low-side driver to a higher level of the fourth capability when the first output detection signal is at the second level in the fourth period; and
(iv-b) set the driving capability of the low-side driver to a lower level of the fourth capability after the first output detection signal changes to the first level.

6. The gate driver circuit according to claim 4,
wherein the control circuit is configured to, when the switching circuit operates in a source mode:
enter the sixth period when assertion of the low-side OFF detection signal occurs in the fourth period, without passing through the fifth period.

7. A gate driver circuit for driving a high-side transistor and a low-side transistor forming a switching circuit, the gate driver circuit comprising:
a high-side driver configured to drive the high-side transistor;
a low-side driver configured to drive the low-side transistor, a driving capability of the low-side driver being switchable in multiple stages including a fourth capability, a fifth capability lower than the fourth capability, and a sixth capability higher than the fourth capability;
a second output sensor configured to compare an output voltage of the switching circuit with a second threshold voltage, and to generate a second output detection signal that takes a first level when the output voltage is higher and takes a second level when the output voltage is lower;
a low-side gate sensor configured to assert a low-side OFF detection signal when a gate-source voltage of the low-side transistor becomes lower than a predetermined voltage level; and
a control circuit configured to switch between a high output state in which the high-side transistor is ON and the low-side transistor is OFF, a low output state in which the high-side transistor is OFF and the low-side transistor is ON, and a high impedance state in which the high-side transistor and the low-side transistor are OFF, by controlling the high-side driver and the low-side driver,
wherein the control circuit is configured to, when the switching circuit operates in a sink mode:
(iv) enter a fourth period when an instruction for transition from the low output state to the high impedance state occurs, and set the driving capability of the low-side driver to the fourth capability in the fourth period;
(v) enter a fifth period when the second output detection signal changes to the first level in the fourth period, and set the driving capability of the low-side driver to the fifth capability in the fifth period; and
(vi) enter a sixth period when assertion of the low-side OFF detection signal occurs in the fifth period, and set the driving capability of the low-side driver to the sixth capability in the sixth period.

8. The gate driver circuit according to claim 7, further comprising:
a first output sensor configured to compare the output voltage of the switching circuit with a first threshold voltage determined to be lower than the second threshold voltage, and to generate a first output detection signal that takes a first level when the output voltage is higher and takes a second level when the output voltage is lower,
wherein the driving capability of the low-side driver is switchable in two levels within the fourth capability, and
wherein the control circuit is configured to, when the switching circuit operates in the sink mode:
(iv-a) set the driving capability of the low-side driver to a higher level of the fourth capability when the first output detection signal is at the second level in the fourth period; and
(iv-b) set the driving capability of the low-side driver to a lower level of the fourth capability after the first output detection signal changes to the first level.

9. The gate driver circuit according to claim 7,
wherein the control circuit is configured to, when the switching circuit operates in a source mode:
enter the sixth period when assertion of the low-side OFF detection signal occurs in the fourth period, without passing through the fifth period.

10. The gate driver circuit according to claim 1, monolithically integrated on a single semiconductor substrate.

11. A motor driver comprising:
a switching circuit including a high-side transistor and a low-side transistor; and
the gate driver circuit according to claim 1, configured to drive the switching circuit.

12. An electronic device comprising:
a motor; and
the motor driver according to claim 11, configured to drive the motor.
